(19) United States
(12) Patent Application Publication
(10) Pub. No.: US 2007/0221623 A1
(43) Pub. Date: Sep. 27, 2007

(54) PLASMA PROCESSING APPARATUS AND METHOD

(75) Inventors: Takahiro HORIGUCHI, Tsukui-gun (JP); Masaki Hirayama, Sendai-shi (JP); Tadahiro Ohmi, Sendai-shi (JP)

Correspondence Address: OBLON, SPIVAK, MCCLELLAND, MAIER & NEUSTADT, P.C., 1940 DUKE STREET, ALEXANDRIA, VA, 22314, US

(73) Assignees: TOKYO ELECTRON LIMITED, Tokyo (JP); Tohoku University, Sendai-shi (JP)

(21) Appl. No.: 11/689,180

(22) Filed: Mar. 21, 2007

(30) Foreign Application Priority Data
Mar. 24, 2006 (JP) 2006-083895

(51) Int. Cl. B44C 1/22; C23C 16/00; C23F 1/00; H05H 1/24

(52) U.S. Cl. 216/69; 118/723 MW; 156/345.36; 427/569

(57) ABSTRACT

There is provided a plasma processing apparatus in which a microwave is propagated into a dielectric body disposed at a top surface of a process chamber through a plurality of slots formed in a bottom face of a rectangular waveguide to excite a predetermined gas supplied into the process chamber into plasma by electric field energy of an electromagnetic field formed on a surface of the dielectric body, to thereby generate plasma with which a substrate is processed, wherein a top face member of the rectangular waveguide is formed of a conductive, nonmagnetic material and is disposed so as to be movable up and down relative to the bottom face of the rectangular waveguide. To change a wavelength in the rectangular waveguide, the top face member of the rectangular waveguide is moved up and down relative to the bottom face of the rectangular waveguide according to conditions of the plasma processing performed in the process chamber, such as gas species, pressure, and a power of the microwave of a microwave supplier.

### BACKGROUND OF THE INVENTION

1. Field of the Invention

The present invention relates to a plasma processing apparatus and a plasma processing method for performing processing such as film formation on a substrate with plasma generated in the apparatus.

2. Description of the Related Art

In manufacturing processes of, for example, a LCD device and the like, an apparatus performing CVD processing, etching processing, and the like to a LCD substrate with plasma generated in a process chamber by the use of a microwave is widely used. As such a plasma processing apparatus, an apparatus in which a plurality of waveguides are arranged in parallel above a process chamber is known (see, for example, Japanese Patent Application Laid-open No. 2004-200646 and Japanese Patent Application Laid-open No. 2004-152876). In a bottom surface of each of the waveguides, a plurality of slots are formed at equal intervals, and further, dielectric bodies in a flat plate shape are provided along the bottom surface of the waveguide. A microwave is propagated to surfaces of the dielectric bodies through the slots, and a predetermined gas (rare gas for plasma excitation and/or gas for plasma processing) supplied into the process chamber is excited into plasma by energy of the microwave (electromagnetic field).

### SUMMARY OF THE INVENTION

In Japanese Patent Application Laid-open No. 2004-200646 and Japanese Patent Application Laid-open No. 2004-152876, for efficient propagation of the microwave through the plurality of slots provided in the bottom face of the waveguide, intervals between the slots are set equal to a predetermined equidistance (interval (λg′/2) half an initially set guide wavelength λg′). However, an actual wavelength of the microwave propagating in the waveguide (guide wavelength) λg is subject to change depending on conditions, such as, for example, gas species and pressure of plasma processing performed in the process chamber. That is, when impedance in the process chamber (in the chamber) changes depending on the conditions of the plasma processing, such as, for example, gas species and pressure, the guide wavelength λg also changes. Therefore, if the plurality of slots are formed at predetermined equal intervals in the bottom face of the waveguide as in Japanese Patent Application Laid-open No. 2004-200646 and Japanese Patent Application Laid-open No. 2004-152876, it is not possible to efficiently propagate the microwave into the process chamber through the dielectric bodies from the plurality of slots because the interval between the slots (λg′/2) deviates from an interval between positions of a peak portion and a valley portion of the actual guide wavelength (λg) due to the change in the guide wavelength λg depending on the conditions (impedance) of the plasma processing. If such a problem is solved by providing a large number of waveguides and plasma processing apparatuses different in interval between the slots in order to change the interval between the slots in the bottom face of the waveguide according to the conditions of each plasma processing, equipment cost enormously increases, and the waveguides and plasma processing apparatuses have to be changed for every plasma processing and thus continuous processing cannot be performed and actual processes cannot be performed.

In view of the above, it is an object of the present invention to provide a plasma processing apparatus and a plasma processing method capable of eliminating deviation of an interval between slots from a guide wavelength λg.

To attain the above object, according to the present invention, there is provided a plasma processing apparatus in which a microwave is propagated into a dielectric body disposed at a top surface of a process chamber through a plurality of slots formed in a bottom face of a rectangular waveguide to excite a predetermined gas supplied into the process chamber into plasma by electric field energy of an electromagnetic field formed on a surface of the dielectric body, to thereby generate plasma with which a substrate is processed, wherein a top face member of the rectangular waveguide is formed of a conductive, nonmagnetic material and is disposed so as to be movable up and down relative to the bottom face of the rectangular waveguide.

At least one opening may be provided in the rectangular waveguide, and the top face member may be inserted in the rectangular waveguide so as to be movable up and down by means of a member inserted in the opening. The plasma processing apparatus may include a mechanism to move up and down the top face member of the rectangular waveguide relative to the bottom face of the rectangular waveguide. In this case, the mechanism may include a rod moving up and down the top face member and a guide rod constantly keeping the top face member parallel to the bottom face. Further, the guide rod may have calibrations representing a height h of the top face member from the bottom face of the rectangular waveguide.

A plurality of rectangular waveguides may be disposed in parallel to each other above the process chamber. The plurality of slots may be arranged in the bottom face of the rectangular waveguide at equal intervals. Further, a plurality of dielectric bodies are attached to the rectangular waveguide, and one or more of the slots are provided in the bottom face for each of the dielectric bodies. In this case, one or more gas ejecting ports are provided, for supplying the predetermined gas into the process chamber, around each of the plurality of dielectric bodies. The gas ejecting port may be provided in a support member supporting the dielectric body.

Further, one or more first gas ejecting ports are provided, for supplying a first predetermined gas into said process chamber, and one ore more second gas ejecting ports are provided, for supplying a second predetermined gas into said process chamber, around each of said plurality of dielectric bodies. In this case, one of the first gas ejecting port and the second gas ejecting port may be disposed lower than the other.

Further, a power of the microwave may be, for example, 1 W/cm² to 4 W/cm². The dielectric body may have at least one protrusion and at least one recession at the outer bottom surface thereof. A dielectric member may be disposed in each of the slots.

According to another aspect of the present invention, provided is a plasma processing method in which a microwave is propagated into a dielectric body disposed at a top surface of a process chamber through a plurality of slots formed in a bottom face of a rectangular waveguide to excite a predetermined gas supplied into the process chamber into plasma by electric field energy of an electromagnetic field formed on a surface of the dielectric body, to thereby generate plasma with which a substrate is processed, wherein a wavelength of the microwave in the waveguide is controlled by moving up and down a top face member of the rectangular waveguide relative to the bottom face of the rectangular waveguide.

The top face member of the rectangular waveguide may be moved up and down relative to the bottom face of the rectangular waveguide according to a condition of the plasma processing.

Generally, a guide wavelength λg of a microwave propagating in a rectangular waveguide is represented by the following expression (1):

λg=λ/√{1−(λ/λc)²} (1)

where λ: free space wavelength=C/f (m), λc: cutoff wavelength of the rectangular waveguide=C/fc (m), C: velocity of light=2.99792458×10⁸ (m/sec) (in vacuum), and f: frequency (Hz), fc: cutoff frequency (Hz) of the rectangular waveguide.

Further, in the rectangular waveguide, the following expression (2) holds:

λc=2h(m) (2)

where h: height (m) of a top face from a bottom face of the rectangular waveguide.

That is, increasing the height h of the top face from the bottom face of the rectangular waveguide also increases λc, which then decreases λg. On the other hand, decreasing the height h of the top face from the bottom face of the rectangular waveguide also decreases λc, which then increases λg. Therefore, in the present invention, to eliminate deviation of an interval between slots (λg′/2) from an interval between the positions of a peak portion and a valley portion of an actual guide wavelength λg (wavelength of a standing wave generated by the guide wavelength λg becomes equal to the guide wavelength λg), the height h of the top face from the bottom face of the rectangular waveguide is changed, thereby correcting the guide wavelength λg having changed by impedance in the process chamber which varies according to the conditions of the plasma processing. With this structure, since the peak portions and the valley portions of the guide wavelength λg can be made to coincide with the positions of the slots, it is possible to efficiently propagate the microwave into the dielectric bodies at the top surface of the process chamber from the plurality of slots formed in the bottom face of the rectangular waveguide, and accordingly, the electromagnetic field can be formed uniformly in the entire area above the substrate, which enables uniform plasma processing of the entire surface of the substrate. Further, it is possible to improve adaptability to an increase in size of the substrate. Moreover, since there is no need to change the interval between the slots every time the conditions of the plasma processing are changed, equipment cost can be reduced, and it is also possible to perform different kinds of plasma processing continuously in the same plasma processing apparatus.

### BRIEF DESCRIPTION OF THE DRAWINGS

FIG. 1 is a vertical cross-sectional view (X-X cross section in FIG. 2) showing a schematic construction of a plasma processing apparatus according to an embodiment of the present invention;

FIG. 2 is a bottom view of a lid;

FIG. 3 is an enlarged vertical cross-sectional view (Y-Y cross section in FIG. 2) showing a part of the lid;

FIG. 4 is an enlarged view of a dielectric body seen from under the lid;

FIG. 5 is a vertical cross-sectional view of the dielectric body taken along the X-X line in FIG. 4;

FIG. 6 is an explanatory view of an embodiment where second gas ejecting ports are disposed lower than first gas ejecting ports;

FIG. 7 is a vertical cross-sectional view showing an embodiment where the inside of a slot is divided in a vertical direction and a plurality of dielectric members of different kinds are disposed therein;

FIG. 8 is a vertical cross-sectional view showing an embodiment where the inside of the slot is divided in a lateral direction and a plurality of dielectric members of different kinds are disposed therein;

FIG. 9 is a graph showing results obtained in an example when a change of film thickness depending on the distance from an end of the rectangular waveguide is studied while the height of a top face of a rectangular waveguide is changed; and

FIGS. 10(a), 10(b) are explanatory views schematically showing the position of an electric field generated in the rectangular waveguide when the height of the top face of the rectangular waveguide is changed.

### DETAILED DESCRIPTION OF THE INVENTION

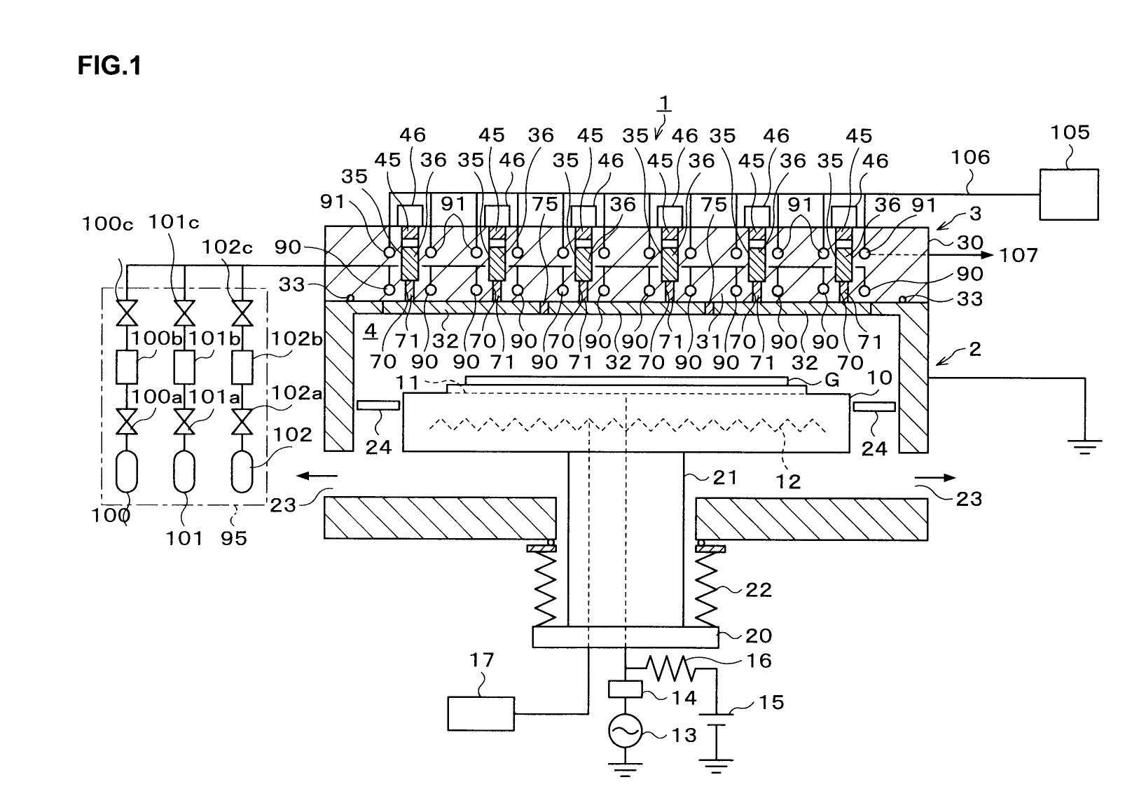

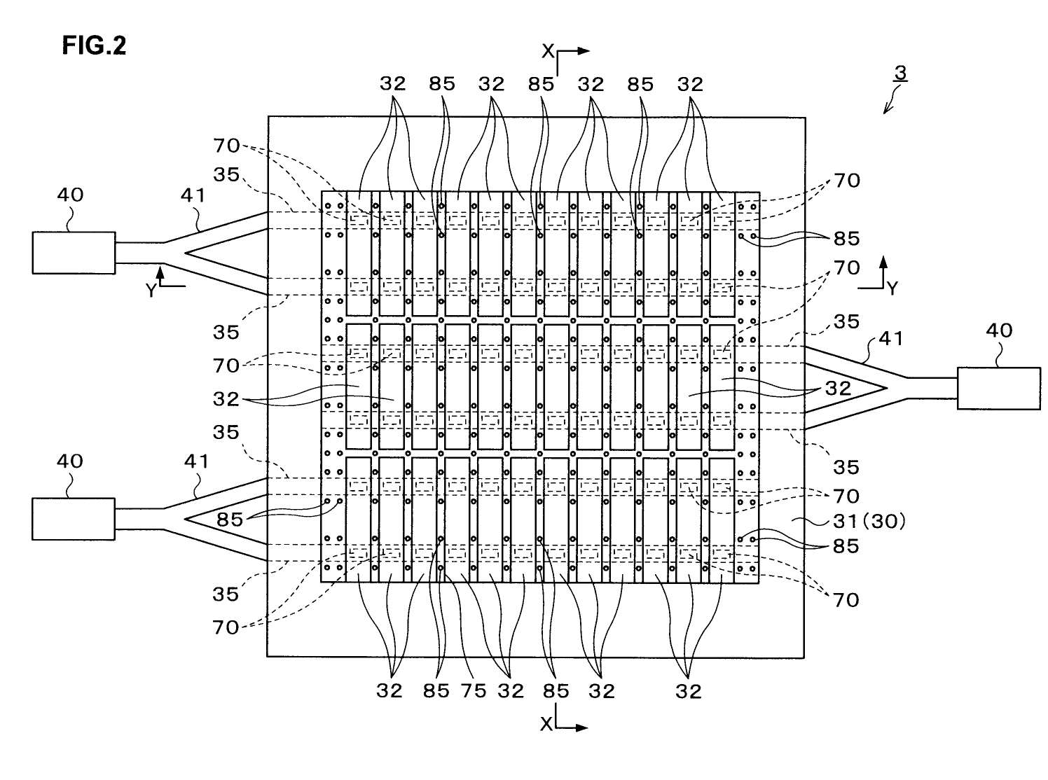

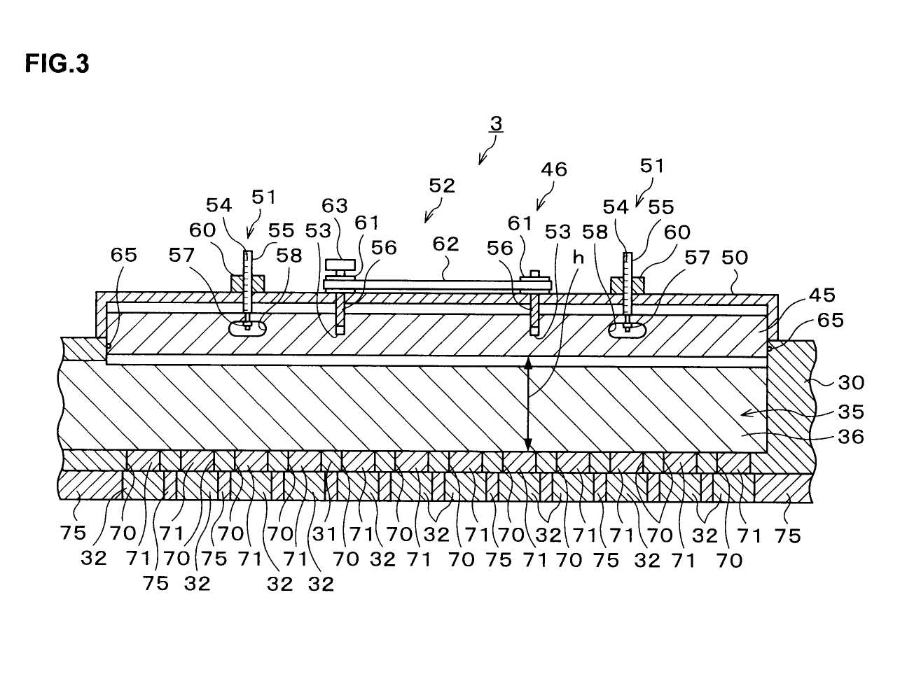

Hereinafter, embodiments of the present invention will be described based on a plasma processing apparatus 1 performing CVD (chemical vapor deposition) processing as an example of plasma processing. FIG. 1 is a vertical cross-sectional view (X-X cross section in FIG. 2) showing a schematic construction of the plasma processing apparatus 1 according to an embodiment of the present invention. FIG. 2 is a bottom view of a lid 3 included in the plasma processing apparatus 1. FIG. 3 is an enlarged vertical cross-sectional view (Y-Y cross section in FIG. 2) showing a part of the lid 3.

This plasma processing apparatus 1 includes: a process vessel 2 in a bottomed cubic shape with its top being open; and the lid 3 covering the top of the process vessel 2. When the top of the process vessel 2 is covered by the lid 3, a process chamber 4 which is an airtight space is formed in the process vessel 2. These process vessel 2 and lid 3 are made of a conductive, nonmagnetic material, for example, aluminum, and are both electrically grounded.

In the process chamber 4, a susceptor 10 as a mounting table for placing, for example, a glass substrate (hereinafter, referred to as a “substrate”) as a substrate thereon is provided. This susceptor 10 is made of, for example, aluminum nitride, and a power feeding part 11 for electrostatically attracting the substrate G and applying predetermined bias voltage to the inside of the process chamber 4 and a heater 12 for heating the substrate G to a predetermined temperature are provided in the susceptor 10. A high-frequency power source 13 for bias application and a high-voltage DC power source 15 for electrostatic attraction which are provided outside the process chamber 4 are connected to the power feeding part 11 via a matching device 14 including a capacitor and so on and via a coil 16, respectively. Likewise, an AC power source 17 provided outside the process chamber 4 is connected to the heater 12.

The susceptor 10 is supported on a lift plate 20 provided under and outside the process chamber 4, via a cylinder 21, and the susceptor 10 moves up and down integrally with the lift plate 20, so that a height of the susceptor 10 in the process chamber 4 is adjusted. However, the inside of the process chamber 4 is kept airtight since a bellows 22 is provided between a bottom surface of the process vessel 2 and the lift plate 20.

In a bottom portion of the process vessel 2, provided is an exhaust port 23 through which an atmosphere in the process chamber 4 is exhausted by an exhaust device (not shown) such as a vacuum pump provided outside the process chamber 4. Further, in the process chamber 4, a rectifying plate 24 for controlling the flow of gas in the process chamber 4 to a preferable state is provided around the susceptor 10.

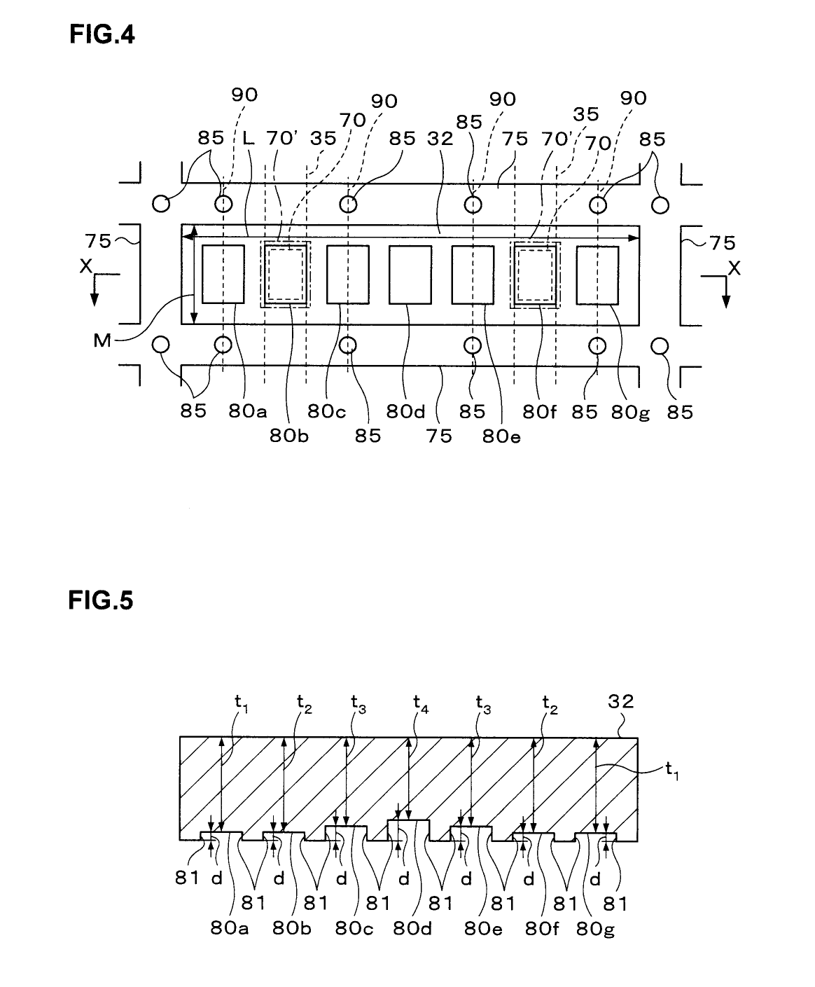

The lid 3 is structured such that a slot antenna 31 is integrally formed on a bottom surface of a lid main body 30 and a plurality of dielectric bodies 32 in a tile form are attached on a bottom surface of the slot antenna 31. The lid main body 30 and the slot antenna 31 are integrally formed of a conductive material, for example, aluminum, and are electrically grounded. As shown in FIG. 1, in a state where the top of the process vessel 2 is covered by the lid 3, the process chamber 4 is kept airtight by an O-ring 33 disposed between a peripheral portion of the bottom surface of the lid main body 30 and a top surface of the process vessel 2 and by O-rings disposed around later-described slots 70 (arrangement positions of the O-rings are shown by dashed lines 70′ in FIG. 4).

In the lid main body 30, a plurality of rectangular waveguides 35 each having a rectangular cross section are horizontally arranged. In this embodiment, six rectangular waveguides 35 all extending in straight line are provided, and the rectangular waveguides 35 are arranged side by side to be parallel to each other. In this embodiment, an aluminum member serving as the lid main body 30 is shaved from the top and grooves are formed, thereby forming the parallel six rectangular waveguides 35 in the lid main body 30, and the bottom surface of the lid main body 30 left shaved is formed as the slot antenna 31. Incidentally, as will be described later, a plurality of slots 70 as through holes are formed in the bottom surface of the lid main body 30 along a bottom face of each of the rectangular waveguides 35, and a bottom portion of the lid main body 30 corresponding to the thickness of the slots 70 serves as the antenna 31. Each of the rectangular waveguides 35 is set with a longer side direction of its cross sectional shape (rectangular shape) being an H plane and vertical and with a shorter side direction being an E plane and horizontal. How the longer side direction and the shorter side direction are set varies depending on each mode. The inside of each of the rectangular waveguides 35 is filled with a dielectric member 36 of, for example, fluorocarbon resin (for example, Teflon (registered trademark)). Examples of the material usable as the dielectric member 36 other than fluorocarbon resin are dielectric materials such as Al₂O₃, quartz, and the like.

Outside the process chamber 4, three microwave suppliers 40 are provided in this embodiment, as shown in FIG. 2, and from each of the microwave suppliers 40, a microwave of, for example, 2.45 GHz is introduced into two of the rectangular waveguides 35 provided in the lid main body 30. Between each of the microwave suppliers 40 and the two rectangular waveguides 35, a Y-branch pipe 41 for distributing the microwave to the two rectangular waveguides 35 is connected.

As shown in FIG. 1, an opening is provided in an upper face of each of the rectangular waveguides 35 and is positioned in a top surface of the lid main body 30, and top face members 45 are inserted in the respective rectangular waveguides 35 from an upper side of thus opening rectangular waveguides 35 to be movable up and down. The top face members 45 are also made of a conductive, nonmagnetic material, for example, aluminum.

The bottom faces of the rectangular waveguides 35 formed in the lid main body 30 constitute the slot antenna 31 formed integrally on the bottom surface of the lid main body 30. As described above, since the shorter side direction of inner surfaces of the rectangular waveguides 35 having the rectangular cross sectional shape is the E plane, the bottom surfaces of the top face members 45 and the top surface of the slot antenna 31 both of which face the inside of the rectangular waveguides 35 are the E planes. Above the lid main body 30, lift mechanisms 46 moving up and down the top face members 45 of the rectangular waveguides 35 relative to the bottom faces of the rectangular waveguides 35 (relative to the slot antenna 31) while keeping the top face members 45 horizontal are provided for the respective waveguides 35.

As shown in FIG. 3, the top face member 45 of the rectangular waveguide 35 is disposed in a cover member 50 attached to cover the top surface of the lid main body 30. In the cover member 50, a space high enough for the top face member 45 of the rectangular waveguide 35 to move up and down therein is formed. On a top surface of the cover member 50, a pair of guide parts 51 and a lift part 52 sandwiched between the guide parts 51 are disposed, and these guide parts 51 and lift part 52 constitute the lift mechanism 46 moving up and down the top face member 45 of the rectangular waveguide 35 while keeping the top face member 45 horizontal.

The top face member 45 of the rectangular waveguide 45 is suspended from the top surface of the cover member 50 via a pair of guide rods 55 provided in the respective guide parts 51 and a pair of lift rods 56 provided in the lift part 52. The lift rods 56 are constituted by screws, and lower ends of the lift rods 56 are screw-fitted (screwed) into screw holes 53 formed in a top surface of the top face member 45, so that the top face member 45 of the rectangular waveguide 35 is supported without falling in the cover member 50.

Stopper nuts 57 are attached to lower ends of the guide rods 55, and the nuts 57 are fastened and fixed in hole portions 58 formed in the top face member 45 of the rectangular waveguide 35, so that the pair of guide rods 55 are vertically fixed to the top surface of the top face member 45.

Upper ends of these guide rods 55 and lift rods 56 penetrate the top surface of the cover member 50 to protrude upward. The upper ends of the guide rods 55 protruding in the guide portions 51 penetrate the inside of guides 60 fixed to the top surface of the cover member 50, so that the guide rods 55 are capable of making sliding movement in the vertical direction in the guides 60. By the guide rods 55 thus making the sliding movement in the vertical direction, the top face member 45 of the rectangular waveguide 35 is constantly kept horizontal, and the top face member 45 of the rectangular waveguide 35 and the bottom face of the rectangular waveguide 35 (top surface of the slot antenna 31) are constantly kept parallel to each other.

Further, the guide rods 55 thus penetrating the inside of the guides 60 have, on their peripheral surfaces, calibrations 54 representing a later-described height h of the top face of the rectangular waveguide 35 (bottom surface of the top face member 45) from the bottom face of the rectangular waveguide 35.

To the upper ends of the lift rods 56 protruding in the lift part 52, timing pulleys 61 are fixed. Since the timing pulleys 61 are placed on the top surface of the cover member 50, the top face member 45 screw-fitted (screwed) into the lower ends of the lift rods 56 are supported in the cover member 50 without falling.

The timing pulleys 61 attached to the pair of lift rods 56 are simultaneously rotated by a timing belt 62. Further, a rotation handle 63 is attached to the upper end portion of the lift rod 56, and by a rotary operation of the rotation handle 63, the pair of lift rods 56 are simultaneously rotated via the timing pulleys 61 and the timing belt 62, so that the top face member 45 screw-fitted (screwed) to the lower ends of the lift rods 56 moves up and down in the cover member 50.

In such a lift mechanism 46, in accordance with the rotary operation of the rotation handle 63, the top face member 45 of the rectangular waveguide 35 can be moved up and down in the cover member 50, and at this time, since the guide rods 55 provided in the guide parts 51 make the sliding movement in the vertical direction in the guides 60, so that the top face member 45 of the rectangular waveguide 35 is constantly kept horizontal, and the top face member 45 of the rectangular waveguide 35 and the bottom face of the rectangular waveguide 35 (top surface of the slot antenna 31) are kept constantly parallel to each other.

As described above, since the dielectric member 36 is filled in the rectangular waveguide 35, the top face member 45 of the rectangular waveguide 35 can move down to a position where it comes into contact with a top surface of the dielectric member 36. By moving the top face member 45 of the rectangular waveguide 35 up and down in the cover member 50, with the lower limit of the movement being the position where the top face member 45 comes into contact with the top surface of the dielectric member 36, it is possible to arbitrarily change the height h of the top face of the rectangular waveguide 35 (bottom surface of the top face member 45) from the bottom face of the rectangular waveguide 35 (top surface of the slot antenna 31) (height h between the bottom surface of the top face member 45 of the rectangular waveguide 35 and the top surface of the slot antenna 31, which are the E planes) by the rotary operation of the rotation handle 63. Further, by reading the calibrations 54 provided on the peripheral surfaces of the guide rods 55, it is possible to know the height h of the top face of the rectangular waveguide 35 (bottom surface of the top face member 45) from the bottom face of the rectangular waveguide 35, which is thus changed by the rotary operation of the rotation handle 63. Incidentally, the height of the cover member 50 is set so that the top face member 45 of the rectangular waveguide 35 can be moved sufficiently high when being moved up and down according to the condition of the plasma processing performed in the process vessel 4, as will be described later.

The top face member 45 is made of a conductive, nonmagnetic material, for example, aluminum or the like, and a shield spiral 65 to ensure electrical continuity to the lid main body 30 is attached to the peripheral surface portion of the top face member 45. To decrease electrical resistance, a surface of the shield spiral 65 is plated with, for example, gold or the like. All of inner wall surfaces of the rectangular waveguide 35 are made of conductive members in electrical continuity to each other, so that current smoothly flows along all the inner wall surfaces of the rectangular waveguide 35 without any discharge.

In the bottom faces of the rectangular waveguides 35 constituting the slot antenna 31, the plurality of slots 70 as through holes are arranged at equal intervals along a longitudinal direction of the rectangular waveguides 35. In this embodiment, assuming G5 (G5 represents the dimension of the substrate G: 1100 mm×1300 mm and the inside dimension of the process chamber 4: 1470 mm×1590 mm), 12 slots 70 are arranged in series for each of the rectangular waveguides 35, and the whole slot antenna 31 has totally 72 (12×6 rows) slots 70 which are uniformly distributed in the entire bottom surface of the lid main body 30 (in the slot antenna 31). An interval between the slots 70 is set so that center axes of the slots 70 adjacent to each other in the longitudinal direction of each of the waveguides 35 are apart from each other by, for example, λg′/2 (λg′ is a guide wavelength of the microwave at the time of initial setting in a case of 2.45 GHz). Incidentally, the number of the slots 70 formed in each of the rectangular waveguides 35 may be any, and for example, with 13 slots 70 being provided for each of the rectangular waveguides 35, totally 78 (13×6 rows) slots 70 for the entire slot antenna 31 may be distributed in the bottom surface of the lid main body 30 (in the slot antenna 31).

In each of the slots 70 thus uniformly distributed in the entire slot antenna 31, a dielectric member 71 made of, for example, Al₂O₃ is filled. Incidentally, as the dielectric member 71, a dielectric material such as, for example, fluorocarbon resin or quartz is usable. Further, the plurality of dielectric bodies 32 attached to the bottom surface of the slot antenna 31 as described above are arranged under the slots 70. Each of the dielectric bodies 32 is in a rectangular flat plate shape, and is made of a dielectric material such as, for example, quartz glass, AlN, Al₂O₃, sapphire, SiN, or ceramics.

As shown in FIG. 2, each of the dielectric bodies 32 is arranged to bridge a gap between the two rectangular waveguides 35 which are connected to one microwave supplier 40 via the Y branch pipe 41. As previously described, totally the six rectangular waveguides 35 are provided in parallel to one another in the lid main body 30, and three rows of the dielectric bodies 32 are arranged, each of the rows corresponding to the two rectangular waveguides 35.

As previously described, in the bottom face of each of the rectangular waveguides 35 (in the slot antenna 31), the 12 slots 70 are arranged in series, and each of the dielectric bodies 32 is attached to bridge the gap between the slots 70 of the two adjacent rectangular waveguides 35 (the two rectangular waveguides 35 connected to the same microwave supplier 40 via the Y branch pipe 41). Therefore, on the bottom surface of the slot antenna 31, totally 36 (12×3 rows) dielectric bodies 32 are attached. To support these 36 dielectric bodies 32 in the arrangement state of 12×3 rows, a beam 75 in a grid form is provided on the bottom surface of the slot antenna 31. Incidentally, the number of the slots 70 formed in the bottom face of each of the waveguides 35 may be any, and, for example, with 13 slots 70 being formed in the bottom face of each of the rectangular waveguides 35, totally 39 (13×3 rows) 39 dielectric bodies 32 may be arranged in the bottom surface of the slot antenna 31.

Here, FIG. 4 is an enlarged view of the dielectric body 32 seen from under the lid 3. FIG. 5 is a vertical cross-sectional view of the dielectric body 32 taken along the X-X line in FIG. 4. The beam 75 is disposed to surround the periphery of each the dielectric bodies 32, and supports the dielectric bodies 32 so as to keep the dielectric bodies 32 in close contact with the bottom surface of the slot antenna 31. The beam 75 is made of a nonmagnetic, conductive material such as, for example, aluminum, and is electrically grounded together with the slot antenna 31 and the lid main body 30. The beam 75 supports the periphery of each of the dielectric bodies 32, so that most of the bottom surface of each of the dielectric bodies 32 is exposed to the inside of the process chamber 4.

Gaps between the dielectric bodies 32 and the slots 70 are sealed with sealing members such as the O-rings 70′. The microwave is introduced into each of the rectangular waveguides 35 formed in the lid main body 30 in, for example, an atmospheric state, but since the gaps between the dielectric bodies 32 and the slots 70 are thus sealed, the inside of the process chamber 4 is kept airtight.

Each of the dielectric bodies 32 is formed in a rectangular shape, with its longitudinal length L being longer than a free space wavelength λ=about 120 mm of the microwave in the vacuumed process chamber 4 and its widthwise length M being shorter than the free space wavelength λ. When the microwave supplier 40 generates the microwave of, for example, 2.45 GHz, the wavelength λ of the microwave propagating on a surface of the dielectric body is substantially equal to the free space wavelength λ. Therefore, the longitudinal length L of each of the dielectric bodies 32 is set longer than 120 mm, for example, to 188 mm. Further, the widthwise length M of each of the dielectric bodies 32 is set shorter than 120 mm, for example, to 40 mm.

Further, the bottom surface of each of the dielectric bodies 32 has protrusion and recessions. Specifically, in this embodiment, seven recessions 80a, 80b, 80c, 80d, 80e, 80f, 80g are arranged in series along the longitudinal direction in the bottom surface of each of the dielectric bodies 32 formed in the rectangular shape. These recessions 80a to 80g have substantially the same rectangular shape in a plane view. Inner side surfaces of the recessions 80a to 80g are substantially vertical wall surfaces 81.

Depths d of the respective recessions 80a to 80g are not all equal but part or all of them are different. In an embodiment shown in FIG. 5, the recessions 80b, 80f closest to the slots 70 have the smallest depth d, and the recession 80d farthest from the slots 70 has the largest depth d. The recessions 80a, 80c and the recessions 80e, 80g positioned on both sides of the recessions 80b, 80f directly under the slots 70 have the depth d between the depth d of the recessions 80b, 80f directly under the slots 70 and the depth d of the recession 80d farthest from the slot 70.

However, as for the recessions 80a, 80g positioned on longitudinal both ends of the dielectric body 32 and the recessions 80c, 80e positioned on inner sides of the two slots 70, the depth d of the recessions 80a, 80g on the both ends is smaller than the depth d of the recessions 80c, 80e positioned on the inner sides of the slots 70. Therefore, in this embodiment, the depths d of the recessions 80a to 80g have the following relation: the depth d of the recessions 80b, 80f closest to the slots 70<the depth d of the recessions 80a, 80g positioned on the longitudinal both ends of the dielectric body 32<the depth d of the recessions 80c, 80e positioned on the inner sides of the slots 70<the depth of the recession 80d farthest from the slots 70.

A thickness t₁ of the dielectric body 32 at positions of the recession 80a and the recession 80g, a thickness t₂ of the dielectric body 32 at positions of the recession 80b and the recession 80f, and a thickness t₃ of the dielectric body 32 at positions of the recession 80c and the recession 80e are set so that substantially no interference occurs between the propagation of the microwave at the positions of the recessions 80a to 80c and the propagation of the microwave at the positions of the recessions 80e to 80g when the microwave propagates in the dielectric body 32, as will be described later. On the other hand, a thickness t₄ of the dielectric body 32 at a position of the recession 80d is set so that so-called cutoff is generated at the position of the recession 80d and substantially no propagation of the microwave takes place at the position of the recession 80d when the microwave propagates in the dielectric body 32, as will be described later. Consequently, the propagation of the microwave at the positions of the recessions 80a to 80c disposed on the side of the slot 70 of one of the rectangular waveguides 35 and the propagation of the microwave at the positions of the recessions 80e to 80g disposed on the side of the slot 70 of the other rectangular waveguide 35 are cut off at the position of the recession 80d, so that they do not interfere with each other, which prevents the interference between the microwave coming out from the slots 70 of the one rectangular waveguide 35 and the microwave coming out from the slots 70 of the other rectangular waveguide 35.

In a bottom surface of the beam 75 supporting the dielectric bodies 32, gas ejecting ports 85 are provided, for supplying predetermined gas into the process chamber 4, around the dielectric bodies 32. The plural gas ejecting ports 85 are formed for each of the dielectric bodies 32 so as to surround the periphery thereof and are uniformly distributed on the entire top surface of the process chamber 4.

As shown in FIG. 1, gas pipes 90 for supply of predetermined gas and cooling water pipes 91 for cooling water supply are provided in the lid main body 30. As shown by the dotted lines 90 in FIG. 4, the gas pipes 90 penetrate the inside of the lid main body 30 in a lateral direction above the gas ejecting ports 85 opening in the bottom surface of the beam 75, and the predetermined gas supplied through the gas pipes 90 are supplied to the gas ejecting ports 85 provided in the bottom surface of the beam 75.

A gas supply source 95 for predetermined gas supply disposed outside the process chamber 4 is connected to the gas pipes 90. As the gas supply source 95 for predetermined gas supply, an argon gas supply source 100, a gas supply source 101 for silane gas as film-forming gas, and a hydrogen gas supply source 102 are prepared in this embodiment, and these gas supply sources 100, 101, 102 are connected to the gas pipes 90 via valves 100a, 101a, 102a, massflow controllers 100b, 101b, 102b, and valves 100c, 101c, 102c respectively. With this structure, the predetermined gases supplied from the predetermined gas supply source 95 to the gas pipes 90 are ejected into the process chamber 4 from the gas ejecting ports 85.

A cooling water supply pipe 106 and a cooling water return pipe 107 for supply and circulation of the cooling water from a cooling water supply source 105 disposed outside the process chamber 4 are connected to the cooling water pipes 91. The cooling water is circulated and supplied from the cooling water supply source 105 to the cooling water pipes 91 through the cooling water supply pipe 106 and the cooling water return pipe 107, so that the lid main body 30 is kept at a predetermined temperature.

Next, a case where, for example, an amorphous silicon film is formed in the plasma processing apparatus 1 according to the embodiment of the present invention as constructed above will be described. At the time of the processing, the substrate G is placed on the susceptor 101 in the process chamber 4, and while a predetermined gas, for example, a mixed gas of an argon gas/a silane gas/a hydrogen gas, is supplied into the process chamber 4 from the process gas supply source 95 through the gas pipes 90 and the gas ejecting ports 85, the inside of the process chamber 4 is exhausted through the exhaust port 23 to be set to a predetermined pressure. In this case, the predetermined gas is ejected from the gas ejecting ports 85 distributed in the entire bottom surface of the lid main body 30, so that the predetermined gas can be supplied evenly to the entire surface of the substrate G placed on the susceptor 10.

Then, along with the supply of the predetermined gas into the process chamber 4, the substrate G is heated to a predetermined temperature by the heater 12. Further, the microwave of, for example, 2.45 GHz generated in the microwave suppliers 40 shown in FIG. 2 is introduced into the rectangular waveguides 35 through the Y branch pipes 41 to propagate in the dielectric bodies 32 through the slots 70.

When the microwave introduced into the rectangular waveguides 35 is thus propagated to the dielectric bodies 32 through the slots 70, if the slots 70 are not large enough, the microwave does not enter the inside of the slots 70 from the rectangular waveguides 35. However, in this embodiment, the inside of each of the slots 70 is filled with the dielectric member 71 higher in dielectric constant than air, such as, for example, fluorocarbon resin, Al₂O₃, or quartz. Therefore, the dielectric members 71 enable the slots 70 even with insufficient size to function equivalently to the slots 70 visually having a size large enough for the microwave to enter. This can ensure that the microwave introduced into the rectangular waveguides 3 5 propagates into the dielectric bodies 32 through the slots 70.

In this case, a dielectric body satisfying the following is selected: λg/√ε≦2a, where a is a length of the slot 70 in the longitudinal direction of the waveguide 35, λg is a wavelength of the microwave propagating in the rectangular waveguide 35 (guide wavelength), and ε is a dielectric constant of the dielectric member 71 disposed in the slot 70. For example, as for fluorocarbon resin, Al₂O₃, and quartz, when the dielectric member 71 made of Al₂O₃ with the highest dielectric constant is disposed in the slot 70, the largest amount of the microwave can be propagated to the dielectric body 32 from the slot 70. Further, as for the slots 70 equal in length a in the longitudinal direction of the rectangular waveguide 35, by using materials different in dielectric constant as the dielectric members 71 disposed in the slots 70, it is possible to control an amount of the microwave propagating from the slots 70 to the dielectric bodies 32.

An electromagnetic field is formed on the surfaces of the dielectric bodies 32 in the process chamber 4 by energy of the microwave thus propagated into the dielectric bodies 32, and the predetermined gas in the process vessel 2 is excited into plasma by electric field energy, so that an amorphous silicon film is formed on the surface of the substrate G. In this case, since the recessions 80a to 80g are formed in the bottom surfaces of the dielectric bodies 32, an electric field substantially perpendicular to the inner surfaces (wall surfaces 81) of the recessions 80a to 80g is formed by the energy of the microwave propagated in the dielectric bodies 32, so that it is possible to efficiently generate plasma in the vicinity thereof. Further, a generation spot of the plasma can also be stabilized. Further, since the plurality of recessions 80a to 80g formed in the bottom surfaces of the dielectric bodies 32 are different in the depth d, the plasma can be generated substantially uniformly on the entire bottom surfaces of the dielectric bodies 32. Further, since the lateral width of each of the dielectric bodies 32 is, for example, 40 mm and thus is narrower than the free space wavelength λ=about 120 mm of the microwave, and the longitudinal length of each of the dielectric bodies 32 is, for example, 188 mm and thus is longer than the free space wavelength λ of the microwave, it is possible to propagate a surface wave only in the longitudinal direction of the dielectric bodies 32. Further, the recession 80d provided in the center of each of the dielectric bodies 32 can prevent the mutual interference of the microwaves propagated from the two slots 70.

In the process chamber 4, uniform film formation with less damage to the substrate G is performed with, for example, plasma with low electron temperature of 0.7 eV to 2.0 eV and with high density of 10¹¹ cm⁻³ to 10¹³ cm⁻³. As appropriate conditions of the amorphous silicon film formation, for example, the pressure in the process chamber 4 is 5 Pa to 100 Pa, preferably, 10 Pa to 60 Pa, and the temperature of the substrate G is 200° C. to 450° C., preferably, 250° C. to 380° C. An appropriate size of the process chamber 4 is G3 or larger (G3 represents the dimension of the substrate G: 400 mm×500 mm and the inside dimension of the process chamber 4: 720 mm×720 mm), for example, G4.5 (the dimension of the substrate G: 730 mm×920 mm and the inside dimension of the process chamber 4: 1000 mm×1190 mm) or G5 (the dimension of the substrate G: 1100 mm×1300 mm and the inside diameter of the process chamber 4: 1470 mm×1590 mm). An appropriate power of the microwave of the microwave supplier 40 is 1 W/cm² to 4 W/cm², preferably, 3 W/cm². By setting the power of the microwave of the microwave supplier 40 to 1 W/cm² or more, it is possible to ignite the plasma, enabling relatively stable generation of the plasma. If the power of the microwave supplier 40 is less than 1 Wcm², the plasma does not ignite, or the generation of the plasma becomes very unstable, which is not practical since processes become unstable and nonuniform.

Here, the conditions of such plasma processing performed in the process chamber 4 (for example, gas species, pressure, power of the microwave of the microwave supplier 40, and the like) are appropriately set according to the kind of the processing, but if impedance in the process chamber 4 to the plasma generation changes due to the change of the conditions of the plasma processing, the wavelength of the microwave propagating in each of the rectangular waveguides 35 (guide wavelength λg) is subject to change in accordance with the change in the impedance. Further, since the slots 70 are disposed for each of the rectangular waveguides 35 at predetermined intervals (λg′/2) as described above, if the impedance changes according to the conditions of the plasma processing and the guide wavelength λg accordingly changes, the interval between the slots 70 (λg′/2) does not match the distance half the actual guide wavelength λg. As a result, the microwave cannot be propagated efficiently to the dielectric bodies 32 on the top surface of the process chamber 4 from the plurality of slots 70 arranged along the longitudinal direction of the rectangular waveguides 35.

Therefore, in the embodiment of the present invention, to correct the guide wavelength λg which has changed because the impedance has changed according to the conditions of the plasma processing performed in the process chamber 4, such as, for example, gas species, pressure, or power of the microwave of the microwave supplier 40, the top face members 45 of the rectangular waveguides 35 are moved up and down relative to the bottom faces (top surface of the slot antenna 31). Specifically, when the actual guide wavelength λg decreases according to the conditions of the plasma processing in the process chamber 4, the rotation handle 63 of the lift mechanism 46 is rotary operated to move down the top face member 45 of the rectangular waveguide 35 in the cover member 50. Thus lowering the height h of the top face of the rectangular waveguide 35 (bottom surface of the top face member 45) from the bottom face of each of the rectangular waveguides 35 causes an incremental change of the guide wavelength λg and accordingly eliminates the deviation of the interval between the slots 70 (λg′/2) from the interval between the positions of the peak portion and the valley portion of the actual guide wavelength λg, which makes it possible to make the peak portions and the valley portions of the guide wavelength λg coincide with the positions of the slots 70. On the other hand, when the actual guide wavelength λg increases according to the conditions of the plasma processing in the process chamber 4, the rotation handle 63 of the lift mechanism 46 is rotary operated to move up the top face member 45 of the rectangular waveguide 35 in the cover member 50. Thus raising the height h of the top face of the rectangular waveguide 35 (bottom surface of the top face member 45) from the bottom face of each of the rectangular waveguides 35 causes a decremental change of the guide wavelength λg and accordingly eliminates the deviation of the interval between the slots 70 (λg′/2) from the interval between the positions of the peak portion and the valley portion of the actual guide wavelength λg, which makes it possible to make the peak portions and the valley portions of the guide wavelength λg coincide with the positions of the slots 70.

Incidentally, when the top face member 45 of the rectangular waveguide 35 is moved up and down in the cover member 50 in this manner, by reading the calibrations 54 provided on the peripheral surface of the guide rods 55 of the lift mechanism 46, it is possible to visually recognize the accurate height h of the top face of the rectangular waveguide 35 (bottom surface of the top face member 45) from the bottom face of the rectangular waveguide 35.

In this manner, it is possible to freely make the peak portions and the valley portions of the actual guide wavelength λg coincide with the positions of the slots 70, by moving up and down the top face member 45 of the rectangular waveguide 35 relative to the bottom face of each of the rectangular waveguides 35 (top surface of the slot antenna 31) to arbitrarily change the height h of the top face of the rectangular waveguide 35 (bottom surface of the top face member 45) from the bottom face of each of the rectangular waveguides 35 and accordingly change the guide wavelength λg of the microwave. As a result, it is possible to efficiently propagate the microwave to the dielectric bodies 32 on the top surface of the process chamber 4 from the plurality of slots 70 formed in the bottom faces of the rectangular waveguides 35, so that a uniform electromagnetic field can be formed in the entire area above the substrate G, which enables uniform plasma processing of the entire surface of the substrate G. Changing the guide wavelength λg of the microwave eliminates the need to change the interval between the slots 70 according to the conditions of each plasma processing, so that it is possible to reduce equipment cost and to continuously perform different kinds of plasma processing in the same process chamber 4.

In addition, according to the plasma processing apparatus 1 of this embodiment, since the plurality of dielectric bodies 32 in the tile form are attached to the top surface of the process chamber 4, each of the dielectric bodies 32 can be made compact and light. This facilitates the manufacture of the plasma processing apparatus 1 and reduces cost, so that it is possible to improve adaptability to an increase in size of the substrate G. Further, the slots 70 are provided for each of the dielectric bodies 32, an area of each of the dielectric bodies 32 is extremely small, and the recessions 80a to 80g are formed in its bottom surface. Therefore, it is possible to efficiently propagate the microwave into the dielectric bodies 32 and efficiently generate the plasma on the entire bottom surface of each of the dielectric bodies 32. This enables uniform plasma processing in the entire process chamber 4. Further, since the beam 75 (support member) supporting the dielectric bodies 32 can be made thinner, most of the bottom surface of each of the dielectric bodies 32 is exposed in the process chamber 4, and the beam 75 hardly obstructs the formation of the electromagnetic field in the process chamber 4, so that a uniform electromagnetic field can be formed in the entire area above the substrate G, which enables uniform generation of the plasma in the process chamber 4.

The gas ejecting ports 85 for supplying the predetermined gas may be provided in the beam 75 supporting the dielectric bodies 32 as in the plasma processing apparatus 1 of this embodiment. Making the beam 75 of metal such as, for example, aluminum as described in this embodiment facilitates machining of the gas ejecting ports 85 and the like.

Hitherto, an example of the preferred embodiment of the present invention has been described, but the present invention is not limited to the forms shown here. For example, the lift mechanism 46 moving up and down the top face member 45 of the rectangular waveguide 35 need not be composed of the guide parts 51 and the lift part 52 as shown in the drawing, but may include a cylinder or other driving mechanism to move up and down the top face member 45 of the rectangular waveguide 35. In the shown form, the top face member 45 of the rectangular waveguide 35 is moved up and down, but lowering the bottom face of the rectangular waveguide 35 is another conceivable alternative for changing the height h of the top face member 45 from the bottom face of the rectangular waveguide 35.

Further, in the described example, the dielectric member 36 made of fluorocarbon resin, Al₂O₃, quartz, or the like is disposed in each of the rectangular waveguides 35, but the inside of each of the rectangular waveguides 35 may be hollow. Incidentally, in the case where the dielectric member 36 is disposed in the rectangular waveguide 35, the guide wavelength λg can be made shorter than in the case where the inside of the rectangular waveguide 35 is hollow. Accordingly, the interval between the slots 70 arranged along the longitudinal direction of the rectangular waveguide 35 can also be made shorter, and accordingly a larger number of the slots 70 can be provided. Consequently, the dielectric bodies 32 can be made smaller and a larger number of the dielectric bodies 32 can be disposed, which can further improve the effects of reduction in size and weight of the dielectric body 32 and uniform plasma processing in the whole process chamber 4.

Incidentally, in the case where the dielectric member 36 is disposed in the rectangular waveguide 35, an upper portion in the rectangular waveguide 35 partly becomes hollow since the top face member 45 moves up and down therein. In this case, the dielectric constant in the rectangular waveguide 35 has a value between a dielectric constant of the dielectric member 36 and a dielectric constant of air existing in the upper portion in the rectangular waveguide 35. For example, if fluorocarbon resin whose dielectric constant is relatively close to that of air (the dielectric constant of air is about 1, the dielectric constant of fluorocarbon resin is about 2) is used as the dielectric member 36, the influence of the size of the hollow portion formed in the upper portion in the rectangular waveguide 35 can be reduced. On the other hand, if, for example, Al₂O₃ whose dielectric constant is greatly different from that of air (the dielectric constant of Al₂O₃ is about 9) is used as the dielectric member 36, the influence of the size of the hollow portion formed in the upper portion in the rectangular waveguide 35 can be increased.

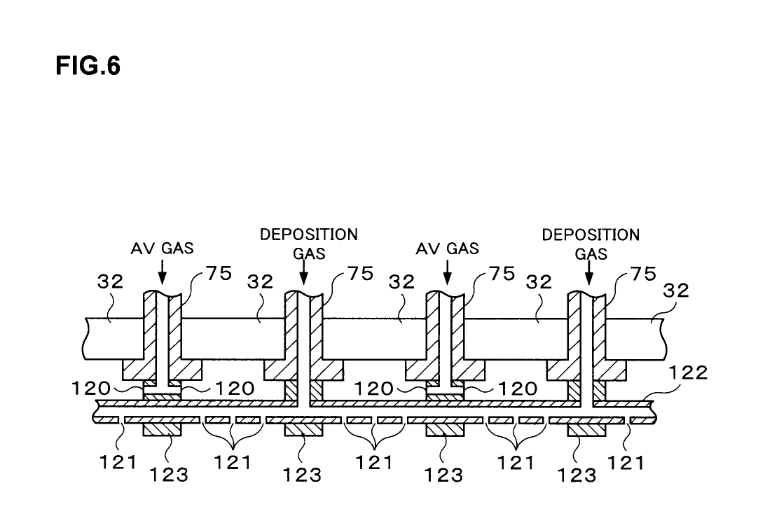

Further, as shown in FIG. 6, one or more first gas ejecting ports 120 for supplying, for example, an Ar gas as a first predetermined gas supplied from the argon gas supply source 100 into the process chamber 4 and one or more second gas ejecting ports 121 for supplying, for example, a film-forming gas as a second predetermined gas supplied from the silane gas supply source 101 and the hydrogen gas supply source 102 into the process chamber 4 may be separately provided around each of the dielectric bodies 32. In the shown example, a pipe 122 is attached in parallel to the bottom surface of the beam 75 by support members 123, being appropriately apart from the bottom surface of the beam 75 supporting the dielectric bodies 32. The first gas ejecting ports 120 are opened in side surfaces of the support members 123 in the vicinity of the bottom surfaces of the dielectric bodies 32, and the Ar gas supplied from the argon gas supply source 100 is supplied into the process chamber 4 through the first gas ejecting ports 120 via the inside of the beam 75 and the support members 123. Further, the second gas ejecting ports 121 are opened in a bottom surface of the pipe 122, and the film-forming gas supplied from the silane gas supply source 101 and the hydrogen gas supply source 102 is supplied into the process chamber 4 through the second gas ejecting ports 121 via the inside of the beam 75, the support members 123, and the pipe 122.

According to such a structure, since the second gas ejecting ports 121 supplying the film-forming gas are disposed lower than the first gas ejecting ports 120 supplying the Ar gas, it is possible to supply the Ar gas in the vicinity of the bottom surfaces of the dielectric bodies 32 and supply the film-forming gas at the positions downwardly apart from the bottom surfaces of the dielectric bodies 32. Consequently, in the vicinity of the bottom surfaces of the dielectric bodies 32, plasma can be generated for the inert Ar gas by a relatively strong electric field and plasma can be generated by a weaker electric field and the Ar plasma for the active film-forming gas. This makes it possible to bring about the operation and effect that the silane gas as the film-forming gas is dissociated to a SiH₃ radical as a precursor and is not dissociated to a SiH₂ radical.

As an example where the bottom surface of the dielectric body 32 has the protrusions and the recessions, the example where the seven recessions 80a to 80g are provided in the bottom surface of the dielectric body 32 is described, but the number, shape, arrangement of the recessions provided in the bottom surface of the dielectric body 32 may be any. The recessions may vary in shape. Further, to form the protrusions and recessions in the bottom surface of the dielectric body 32, protrusions may be provided on the outer bottom surface of the dielectric body 32. In any case, forming the wall surface substantially perpendicular to the bottom surface of the dielectric body by forming the protrusions and the recessions on the bottom surface of the dielectric body 32 makes it possible to form a substantially vertical electric field by the energy of the microwave propagated to the vertical wall surface, which enables efficient generation of the plasma in its vicinity and also can stabilize the generation spot of the plasma.

Further, each of the rectangular waveguides 35 may be arranged so that the longer side direction of its cross sectional shape (rectangular shape) becomes the E plane and horizontal, and the shorter side direction becomes the H plane and vertical. Incidentally, as in the shown embodiment, disposing the rectangular waveguide 35 so that the longer side direction of its cross sectional shape (rectangular shape) becomes the H plane and vertical and the shorter side direction becomes the E plane and horizontal can widen the distance between the rectangular waveguides 35, which facilitates arranging, for example, the gas pipes 90 and the cooling water pipes 91, and also facilitates increasing the number of the rectangular waveguides 35.

The shape of the slots 70 formed in the slot antenna 31 can be any of various shapes, and may be in, for example, a slit shape. Further, a radial line slot antenna may be formed by arranging the plurality of slots 70 spirally or coaxially, instead of arranged them on a straight line. The shape of the dielectric body 32 is not limited to a rectangular shape but may be, for example, a square shape, a triangular shape, any polygonal shape, a disk shape, an elliptical shape, or the like. The dielectric bodies 32 may have the same shape or different shapes.

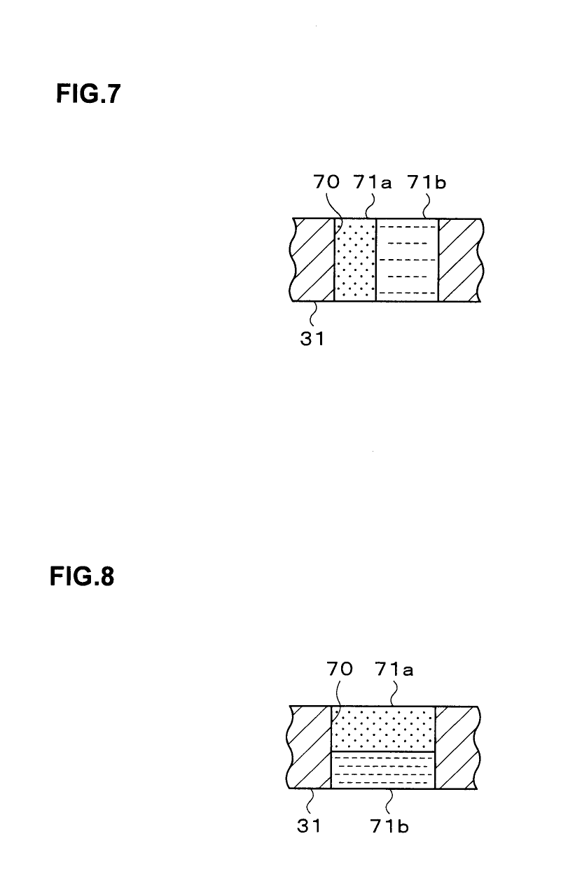

Further, the example where the dielectric member 71 made of fluorocarbon resin, Al₂O₃, quartz, or the like is filled in the slot 70 is described, but a plurality of dielectric members of different kinds may be disposed in each of the slots 70. FIG. 7 and FIG. 8 show examples thereof and embodiments where two different kinds of dielectric members 71a, 71b are disposed in the slot 70. In these cases, for example, as shown in FIG. 7, the two kinds of dielectric members 71a, 71b may be disposed to divide the inside of the slots 70 in the vertical direction into two portions. Alternatively, for example, as shown in FIG. 8, the two kinds of dielectric members 71a, 71b may be disposed to divide the inside of the slot 70 in the lateral direction into two portions.

In a case where the two different kinds of dielectric members 71a, 71b are thus disposed in the slot 70, the two dielectric members 71a, 71b made of different dielectric materials satisfying λg/√ε′≦2a are selected, where a is the length of the slot 70 in the longitudinal direction of the rectangular waveguide 35, λg is the wavelength of the microwave propagating in the rectangular waveguide 35 (guide wavelength), and ε′ is a dielectric constant determined by the combination of the two kinds of dielectric members 71a, 71b disposed in the slot 70. For example, as for fluorocarbon resin, Al₂O₃, and quartz, disposing the combination of the dielectric member 71a made Al₂O₃ with the highest dielectric constant and the dielectric member 71b made of quartz lower in dielectric constant than Al₂O₃ in the slot 70 can produce a state as if a dielectric material lower in dielectric constant than Al₂O₃ and higher in dielectric constant than quartz were disposed in the slot 70. In this case, changing a ratio of Al₂O₃ and quartz can arbitrarily adjust the dielectric constant ε′ determined by the combination of the two kinds of dielectric members 71a, 71b. Likewise, disposing the combination of the dielectric member 71a made of fluorocarbon resin with the lowest dielectric constant and the dielectric member 71b made of quartz higher in dielectric constant than fluorocarbon resin in the slot 70 can produce a state as if a dielectric material lower in dielectric constant than quartz and higher in dielectric constant than fluorocarbon resin were disposed in the slot 70. Also in this case, changing a ratio of quartz and fluorocarbon resin can arbitrarily adjust the dielectric constant ε′ determined by the combination of the two kinds of dielectric members 71a, 71b.

In the shown examples, the two kinds of dielectric members 71a, 71b are disposed to divide the inside of the slot 70 in the vertical direction into two portions (FIG. 7) and to divide the inside of the slot 70 in the lateral direction into two portions (FIG. 8), but the dividing direction is not limited to the vertical direction and the lateral direction. For example, it is also conceivable to divide the inside of the slot 70 in an oblique direction and dispose the two kinds of dielectric members 71a 71b therein. Further, the plurality of dielectric members disposed in the slot 70 is not limited to two kinds but may be three kinds or more.

Thus disposing the combination of the plurality of dielectric members of different kinds in the slot 70 makes it possible to easily produce a state equivalent to a state where a dielectric member having a dielectric constant that cannot be obtained in nature is disposed in the slot 70. This can ensure that the microwave introduced into the rectangular waveguide 35 is propagated to the dielectric bodies 32 through the slots 70.

The above embodiment has described the apparatus performing the amorphous silicon film formation which is an example of the plasma processing, but the present invention is applicable not only to the amorphous silicon film formation but also to oxide film formation, polysilicon film formation, silane ammonia processing, silane hydrogen processing, oxide film processing, silane oxygen processing, other CVD processing, and etching processing.

### EXAMPLE

A SiN film was formed on the surface of the substrate G in the plasma processing apparatus 1 according to the embodiment of the present invention described with reference to FIG. 1 and so on, while the height of the top surface of the rectangular waveguide 35 was varied, and a change of the position of an electric field E in the rectangular waveguide 35 and an influence on plasma generated in the process chamber 4 were studied.

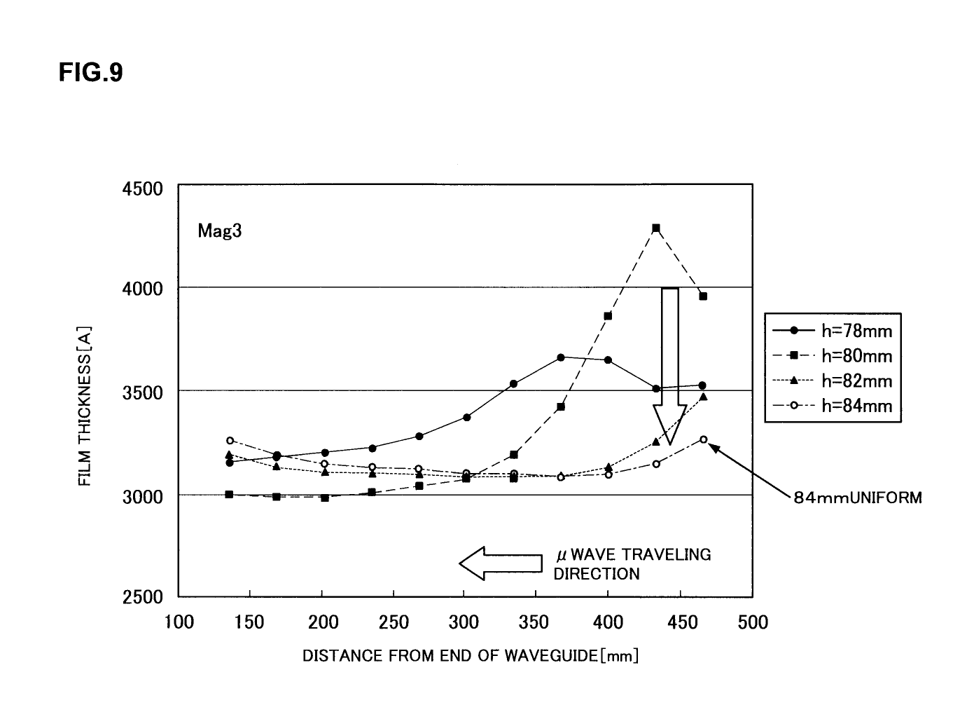

A change in a thickness A of a SiN film formed on the surface of the substrate G depending on the distance from the end of the rectangular waveguide 35 was studied, and the results shown in FIG. 9 were obtained. FIG. 9 shows the correlation between the film thickness (A) of the SiN film and the distance (mm) from the end of the rectangular waveguide 35. The higher the plasma density is, the higher the deposition rate is, and as a result, the larger the thickness of the SiN film becomes, and therefore, it may be thought that the thickness is proportional to the plasma density. The height h of the top face member 45 of the rectangular waveguide 35 was varied to 78 mm, 80 mm, 82 mm, and 84 mm, and the thickness A at each height was examined. When h=84 mm, the change in the thickness A depending on the distance from the end of the rectangular waveguide 35 was the smallest, and it was possible to form a SiN film with a uniform thickness A on the entire surface of the substrate A. On the other hand, when h=78 mm, 80 mm, and 82 mm, the thickness A became large on the front side of the rectangular waveguide 35, and the thickness A decreases as the distance from the end side of the rectangular waveguide 35 is shorter. It can be thought that, except when h=84 mm, a distance half the actual guide wavelength λg does not match the predetermined interval (λg′/2) between the slots 70.

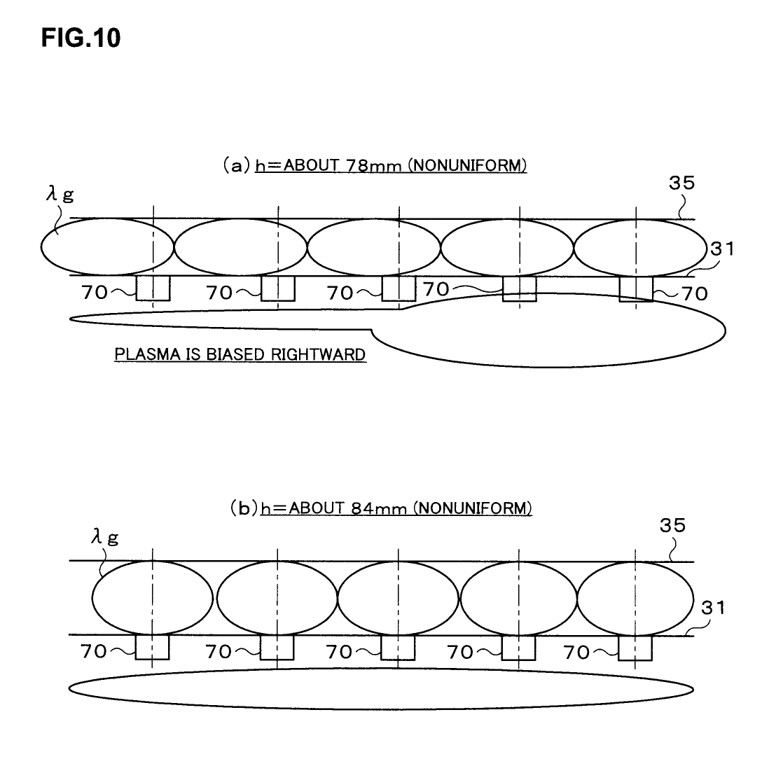

FIGS. 10(a), 10(b) schematically show a change in the guide wavelength λg of the microwave propagating in the rectangular waveguide 35 when the height h of the top surface of the rectangular waveguide 35 is approximately 78 mm and 84 mm. When h=approximately 78, the distance (λg/2) half the actual guide wavelength λg becomes longer due to the influence of impedance of the plasma generated in the process chamber 4, and consequently, the interval between the peak portion and the valley portion of the guide wavelength λg became longer than the interval (λg′/2) between the slots 70 formed in the bottom face of the rectangular waveguide 35 (in the slot antenna 31), as shown in FIG. 10(a). As a result, the peak portions and the valley portions of the guide wavelength λg deviate more from the positions of the slots 70 at positions closer to the end side of the rectangular waveguide 35. Due to this influence, as the distance from the end of the rectangular waveguide 35 is smaller, the microwave propagating to the dielectric body 32 from the slots 70 decreases, which causes nonuniformity in electric field energy and nonuniformity in the plasma, and as a result, nonuniformity of the film formation. On the other hand, when h=approximately 84 mm, as shown in FIG. 10(b), the peak portions and the valley portions of the guide wavelength λg substantially coincided with the positions of the slots 70 formed in the bottom face of the rectangular waveguide 35 (in the slot antenna 31). Consequently, uniform plasma was generated along the longitudinal direction of the rectangular waveguide 35 in the process chamber 4 and the thickness also became substantially uniform. It has been found out that, by thus changing the height h of the top face member 45 of the rectangular waveguide 35 to adjust the actual guide wavelength λg of the microwave propagating in the rectangular waveguide 35, it is possible to make the peak portions and the valley portions of the guide wavelength λg coincide with the positions of the slots 70 and efficiently propagate the microwave to the dielectric bodies 32 on the top surface of the process chamber 4.

What is claimed is:

1. A plasma processing apparatus in which a microwave is propagated into a dielectric body disposed at a top surface of a process chamber through a plurality of slots formed in a bottom face of a rectangular waveguide to excite a predetermined gas supplied into the process chamber into plasma by electric field energy of an electromagnetic field formed on a surface of the dielectric body, to thereby generate plasma with which a substrate is processed,
wherein a top face member of said rectangular waveguide is formed of a conductive, nonmagnetic material and is disposed so as to be movable up and down relative to the bottom face of said rectangular waveguide.

2. The plasma processing apparatus according to claim 1,
wherein at least one opening is provided in an upper face of said rectangular waveguide, and said top face member is inserted in said rectangular waveguide so as to be movable up and down by means of a member inserted in said opening.

3. The plasma processing apparatus according to claim 1, comprising a mechanism to move up and down said top face member of said rectangular waveguide relative to the bottom face of the rectangular waveguide.

4. The plasma processing apparatus according to claim 3,
wherein said mechanism includes a rod moving up and down said top face member and a guide rod constantly keeping said top face member parallel to said bottom face.

5. The plasma processing apparatus according to claim 4,
wherein the guide rod has calibrations representing a height h of said top face member from said bottom face of said rectangular waveguide.

6. The plasma processing apparatus according to claim 1,
wherein a plurality of rectangular waveguides are disposed in parallel to each other above said process chamber.

7. The plasma processing apparatus according to claim 1,
wherein said plurality of slots are arranged in said bottom face of said rectangular waveguide at equal intervals.

8. The plasma processing apparatus according to claim 1,
wherein a plurality of dielectric bodies are attached to said rectangular waveguide, and one or more of said slots are provided in said bottom face for each of said dielectric bodies.

9. The plasma processing apparatus according to claim 8,
wherein one or more gas ejecting ports are provided, for supplying the predetermined gas into said process chamber, around each of said plurality of dielectric bodies.

10. The plasma processing apparatus according to claim 9,
wherein said gas ejecting port is provided in a support member supporting said dielectric body.

11. The plasma processing apparatus according to claim 8,
wherein one or more first gas ejecting ports are provided, for supplying a first predetermined gas into said process chamber, and one ore more second gas ejecting ports are provided, for supplying a second predetermined gas into said process chamber, around each of said plurality of dielectric bodies.

12. The plasma processing apparatus according to claim 11,
wherein one of said first gas ejecting port and said second gas ejecting port is disposed lower than the other.

13. The plasma processing apparatus according to claim 1,
wherein a power of said microwave is 1 W/cm² to 4 W/cm².

14. The plasma processing apparatus according to claim 1,
wherein said dielectric body has at least one protrusion and at least one recession at the outer bottom surface thereof.

15. The plasma processing apparatus according to claim 1,
wherein a dielectric member is disposed in each of the slots.

16. A plasma processing method in which a microwave is propagated into a dielectric body disposed at a top surface of a process chamber through a plurality of slots formed in a bottom face of a rectangular waveguide to excite a predetermined gas supplied into the process chamber into plasma by electric field energy of an electromagnetic field formed on a surface of the dielectric body, to thereby generate plasma with which a substrate is processed,
wherein a wavelength of said microwave in said waveguide is controlled by moving up and down a top face member of said rectangular waveguide relative to the bottom face of said rectangular waveguide.

17. The plasma processing method according to claim 16,
wherein said top face member of said rectangular waveguide is moved up and down relative to said bottom face of said rectangular waveguide according to a condition of the plasma processing.
